(19) United States
(12) Patent Application Publication
(10) Pub. No.: US 2025/0204172 A1
(43) Pub. Date: Jun. 19, 2025

(54) DISPLAY DEVICE AND MANUFACTURING METHOD THEREOF

(71) Applicant: InnoLux Corporation, Miao-Li County (TW)

(72) Inventor: Cheng-Min WU, Miao-Li County (TW)

(73) Assignee: InnoLux Corporation, Miao-Li County (TW)

(21) Appl. No.: 18/953,000

(22) Filed: Nov. 19, 2024

(30) Foreign Application Priority Data
Dec. 18, 2023 (TW) 112149288

(51) Int. Cl. H10K 59/123; H10K 59/12; H10K 59/121; H10K 59/124; H10K 59/126; H10K 59/38

(52) U.S. Cl. CPC H10K 59/123; H10K 59/1201; H10K 59/1213; H10K 59/124; H10K 59/126; H10K 59/38

(57) ABSTRACT

A display device includes a substrate, a transistor, an insulating layer and a color filter. The transistor is disposed on the substrate. The insulating layer is disposed on transistor and includes a side surface. The color filter is disposed on the substrate, and the color filter includes a first portion disposed on the insulating layer and a second portion adjacent to the first portion, wherein the second portion is in contact with the side surface of the insulating layer. A first color filter thickness of the first portion is less than a second color filter thickness of the second portion.

### BACKGROUND OF THE DISCLOSURE

### 1. Field of the Disclosure

The present disclosure relates to a display device and a manufacturing method thereof, and more particularly to a display device having a high pixel aperture ratio and a high yield rate, and to a related manufacturing method of this display device.

### 2. Description of the Prior Art

As the evolution and development of electronic devices, the electronic devices have become an indispensable item. For instance, a display device which is a kind of the electronic device has a displaying function, so as to transmit information and/or display an image.

In the electronic device, the configuration of electronic components and/or structures affects the performance and the yield rate of the electronic device. In the case of the display device, the configuration of electronic components and/or structures affects the pixel aperture ratio and the yield rate of the display device, thereby affecting the displaying performance. For example, in the display device, a thickness of a layer affects a size of an etching hole passing through this layer, thereby affecting the pixel aperture ratio, the displaying performance and the yield rate. For example, the size of the etching hole is enhanced as the thickness of the layer which the etching hole passes through is increased, and the pixel aperture ratio is decreased as the size of the specific etching hole is enhanced, thereby reducing the displaying performance. Therefore, in the electronic device, the suitable configuration of electronic components and/or structures needs to be provided, so as to enhance the performance and the yield rate of the electronic device.

### SUMMARY OF THE DISCLOSURE

According to an embodiment, the present disclosure provides a display device including a substrate, a transistor, an insulating layer and a color filter. The transistor is disposed on the substrate. The insulating layer is disposed on the transistor and includes a side surface. The color filter is disposed on the substrate and includes a first portion disposed on the insulating layer and a second portion adjacent to the first portion, wherein the second portion is in contact with the side surface of the insulating layer. A first color filter thickness of the first portion is less than a second color filter thickness of the second portion.

According to another embodiment, the present disclosure provides a manufacturing method of a display device. The manufacturing method includes: providing a substrate; forming a semiconductor layer on the substrate; forming a gate dielectric layer on the semiconductor layer; forming a gate electrode on the gate dielectric layer; forming an insulating layer on the gate electrode; removing a part of the gate dielectric layer and a part of the insulating layer to form an opening; and forming a color filter on the insulating layer and in the opening. A portion of the color filter disposed in the opening is in contact with a side surface of the gate dielectric layer and a side surface of the insulating layer.

### BRIEF DESCRIPTION OF THE DRAWINGS

FIG. 1 is a schematic diagram showing a top view of a display device according to a first embodiment of the present disclosure.

FIG. 2 is a schematic diagram showing a cross-sectional view of a structure taken along a cross-sectional line A-A′ in FIG. 1.

FIG. 3 is a schematic diagram showing a cross-sectional view of a structure taken along a cross-sectional line B-B′ in FIG. 1.

FIG. 4 is a schematic diagram showing a cross-sectional view of a display device according to a second embodiment of the present disclosure.

FIG. 5 is a schematic diagram showing a top view of a display device according to a third embodiment of the present disclosure.

FIG. 6 is a schematic diagram showing a cross-sectional view of a structure taken along a cross-sectional line C-C′ in FIG. 5.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of an electronic device in this disclosure, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components with the same function but different names.

In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, regions, steps, operations and/or components would be pointed to existence, but not limited to the existence of one or a plurality of the corresponding features, regions, steps, operations and/or components.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each region, and/or each structure may be reduced or enlarged.

When the corresponding component such as layer or region is referred to “on another component”, it may be directly on this another component, or other component(s) may exist between them. On the other hand, when the component is referred to “directly on another component (or the variant thereof)”, any component does not exist between them. Furthermore, when the corresponding component is referred to “on another component”, the corresponding component and the another component have a disposition relationship along a top-view/vertical direction, the corresponding component may be below or above the another component, and the disposition relationship along the top-view/vertical direction are determined by an orientation of the device.

It will be understood that when a component or layer is referred to as being “connected to” another component or layer, it can be directly connected to this another component or layer, or intervening components or layers may be presented. In contrast, when a component is referred to as being “directly connected to” another component or layer, there are no intervening components or layers presented. In addition, when the component is referred to “be coupled to/with another component (or the variant thereof)”, it may be directly connected to this another component, or may be indirectly connected (such as electrically connected) to this another component through other component(s).

In the description and following claims, the term “horizontal direction” generally means a direction parallel to a horizontal plane, the term “horizontal plane” generally means a surface parallel to a direction X and direction Y in the drawings, the term “vertical direction” generally means a direction parallel to a direction Z and perpendicular to the horizontal direction in the drawings, and the direction X, the direction Y and the direction Z are perpendicular to each other. In the description and following claims, the term “top view” generally means a viewing result viewing along the vertical direction. In the description and following claims, the term “cross-sectional view” generally means that a structure cut along the vertical direction is viewed along the horizontal direction.

In the description and following claims, it should be noted that the term “overlap” means that two elements overlap along the direction Z, and the term “overlap” can be “partially overlap” or “completely overlap” in unspecified circumstances.

In the description and following claims, a top surface and a bottom surface of a layer are opposite to each other in the direction Z, and the top surface is higher than the bottom surface in the figures showing the cross-sectional view.

The terms “about”, “approximately”, “substantially”, “equal”, or “same” generally mean within +20% of a given value or range, or mean within +10%, +5%, +3%, +2%, +1%, or +0.5% of a given value or range.

Although terms such as first, second, third, etc., may be used to describe diverse constituent elements, such constituent elements are not limited by the terms. These terms are used only to discriminate a constituent element from other constituent elements in the specification, and these terms have no relation to the manufacturing order of these constituent components. The claims may not use the same terms, but instead may use the terms first, second, third, etc. with respect to the order in which an element is claimed. Accordingly, in the following description, a first constituent element may be a second constituent element in a claim.

It should be noted that the technical features in different embodiments described in the following can be replaced, recombined, or mixed with one another to constitute another embodiment without departing from the spirit of the present disclosure.

In the present disclosure, the electronic device may include a display device, a lighting device, an antenna device, a sensing device, a tiled device or a combination thereof, but not limited thereto. The display device may be a non-self-luminous type display device or a self-luminous type display device based on requirement(s), and the display device may be a color display device or a monochrome display device based on requirement(s). The antenna device may be a liquid-crystal-type antenna device or a non-liquid-crystal-type antenna device, the sensing device may be a device for sensing capacitance, light, thermal or ultrasonic, and the tiled device may be a tiled display device or a tiled antenna device, but not limited thereto. Electronic components in the electronic device may include passive component(s) and active component(s), such as capacitor(s), resistor(s), inductor(s), diode(s), transistor(s) and/or integrated circuit(s), but not limited thereto. The diode may include a light emitting diode (LED) or a photodiode. The light emitting diode may include an organic light emitting diode (OLED), a mini LED, a micro LED or a quantum dot LED, but not limited thereto. The transistor may include a top gate thin film transistor, a bottom gate thin film transistor or a dual gate thin film transistor, but not limited thereto. The electronic device may include fluorescence material, phosphorescence material, quantum dot (QD) material or other suitable material based on requirement(s), but not limited thereto. The electronic device may have a peripheral system (such as a driving system, a control system, a light system, etc.) for supporting the device(s) and the component(s) in the electronic device.

The following uses the display device as an example to explain the present disclosure, wherein the display device may be a non-self-luminous type color display device with a displaying function, and the display device may have other suitable function based on requirement(s) in addition to the displaying function. Note that the design of the present disclosure may be applied on any suitable electronic device.

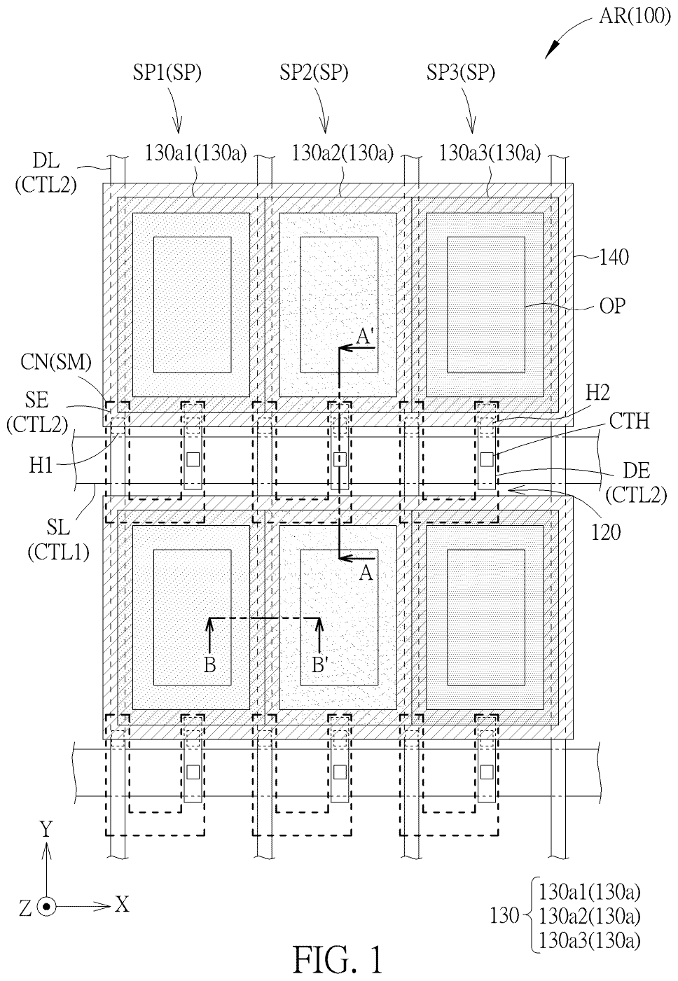

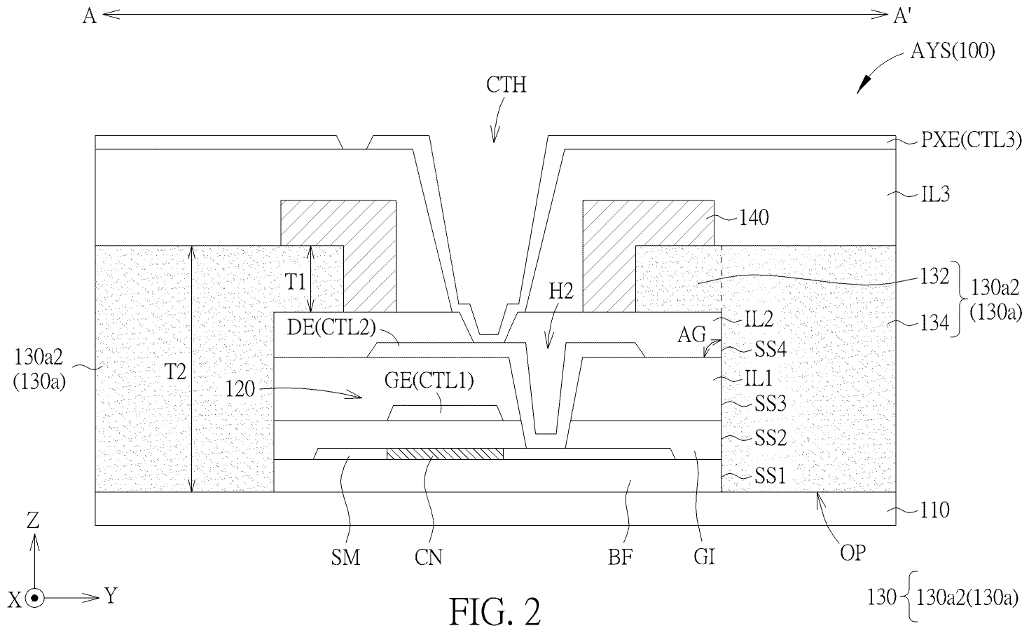

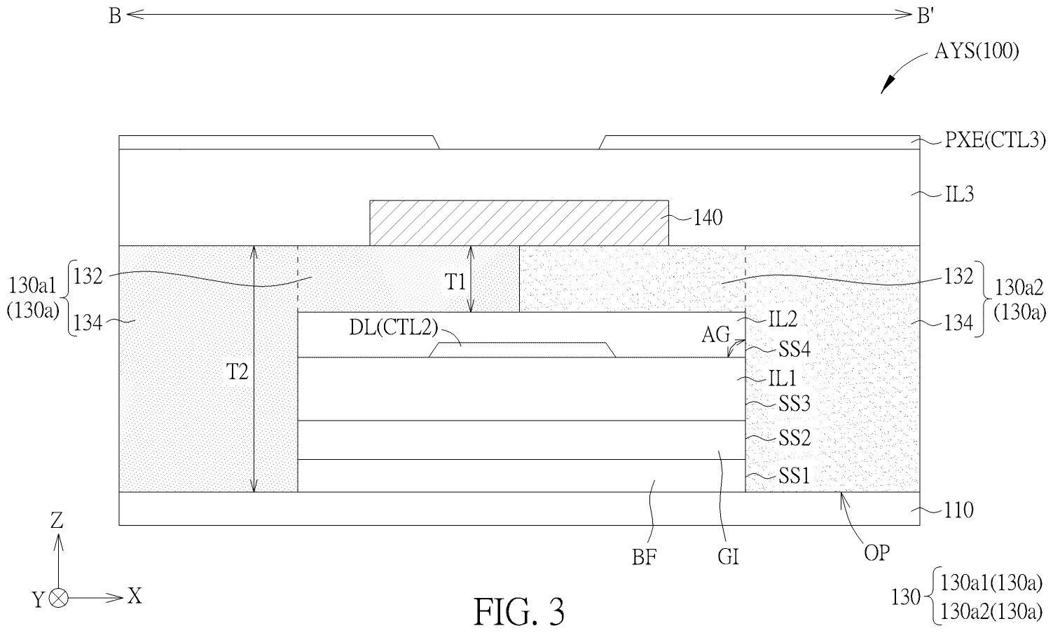

Referring to FIG. 1 to FIG. 3, FIG. 1 is a schematic diagram showing a top view of a display device according to a first embodiment of the present disclosure, FIG. 2 is a schematic diagram showing a cross-sectional view of a structure taken along a cross-sectional line A-A′ in FIG. 1, and FIG. 3 is a schematic diagram showing a cross-sectional view of a structure taken along a cross-sectional line B-B′ in FIG. 1. As shown in FIG. 1, the display device 100 may have an active region AR configured to display an image. The active region AR of the display device 100 may include a plurality pixels, and each pixel may include at least one sub-pixel SP, wherein the pixel is a displaying unit of the display device 100. The number of the sub-pixel(s) SP in each pixel and the color(s) of the sub-pixel(s) SP in each pixel may be designed based on requirement(s). In some embodiments, if the display device 100 is a color display device, one pixel may include a first sub-pixel SP1 (e.g., a red sub-pixel), a second sub-pixel SP2 (e.g., a green sub-pixel) and a third sub-pixel SP3 (e.g., a blue sub-pixel) corresponding to different colors, but not limited thereto. In some embodiments, if the display device 100 is a monochrome display device, one pixel may include one sub-pixel SP, but not limited thereto.

In addition, the arrangement of the pixels and/or the arrangement of the sub-pixels SP may be designed based on requirement(s). In FIG. 1, the pixels and/or the sub-pixels SP may be arranged in the direction X and the direction Y to form an array, but not limited thereto.

The display device 100 may further include a peripheral region (not shown in figures) disposed on at least one outer side of the active region AR, wherein the component(s) and the structure(s) configured to assist in displaying an image may be disposed in the peripheral region. For instance, the peripheral region may surround the active region AR, but not limited thereto.

As shown in FIG. 1 to FIG. 3, the display device 100 may include a substrate 110, and the display device 100 may optionally include an opposite substrate (not shown in figures) opposite to the substrate 110, wherein the substrate 110 and the opposite substrate may be rigid or flexible individually, and the substrate 110 and the opposite substrate may include suitable material based on their types. For instance, the substrate 110 and the opposite substrate may individually include glass, quartz, ceramic, sapphire, polymer (e.g., polyimide (PI), polyethylene terephthalate (PET), etc.), other suitable material(s) or a combination thereof. In the present disclosure, some components and structures of the display device 100 may be disposed on the substrate 110 (or may be disposed between the substrate 110 and the opposite substrate), so as to make the substrate 110 carry these components and structures. Note that a normal direction of the substrate 110 and a normal direction of the opposite substrate may be parallel to the direction Z.

The display device 100 may include a display medium layer, a backlight module and other suitable component, wherein the backlight module may be configured to provide backlight, and the display medium layer may include any suitable display medium material (e.g., liquid crystal molecules). For instance, the substrate 110 may be disposed between the display medium layer and the backlight module, and the display medium layer may be disposed between the substrate 110 and the opposite substrate.

In the present disclosure, the display device 100 may include at least one conductive layer, at least one insulating layer, at least one semiconductor layer or a combination thereof, and these layers are disposed on the substrate 110 to form the electronic components in the display device 100. The material of the conductive layer may include metal, transparent conductive material (such as indium tin oxide (ITO), indium zinc oxide (IZO), etc.), other suitable conductive material(s) or a combination thereof, the material of the insulating layer may include such as silicon oxide (SiOₓ), silicon nitride (silicon oxynitride (SiOₓN_{y}), organic insulating material (e.g., photosensitive resin), other suitable insulating material(s) or a combination thereof, and the material of the semiconductor layer may include such as poly-silicon, amorphous silicon, metal-oxide semiconductor, other suitable semiconductor material(s) or a combination thereof, but not limited thereto. In the present disclosure, the insulating layer may be configured to separate different conductive layers from each other and/or provide a flat surface, but not limited thereto.

In FIG. 2 and FIG. 3, a buffer layer BF, a semiconductor layer SM, a gate dielectric layer GI, a conductive layer CTL1, an insulating layer IL1, a conductive layer CTL2, an insulating layer IL2, an insulating layer IL3 and a transparent conductive layer CTL3 are disposed on the substrate 110 in sequence, and these layers are disposed between the substrate 110 and the display medium layer, but not limited thereto. In some embodiments, the buffer layer BF is disposed between the substrate 110 and the transistor 120, so as to reduce impurities in the substrate 110 from affecting the electrical properties of the transistor 120, but not limited thereto. In some embodiments, the insulating layer IL3 may have a flattening function and provide a flat surface, so as to serve as a flattening layer, but not limited thereto. Note that the disposing order of these layers described above is an example, and the disposing order of these layers may be changed based on requirement(s).

As shown in FIG. 1 to FIG. 3, the display device 100 may include a transistor 120 disposed on the substrate 110 and disposed in the sub-pixel SP, wherein the transistor 120 may include a plurality of aforementioned layers. In some embodiments, the transistor 120 may be a thin film transistor. For instance, the transistor 120 may be a top gate thin film transistor, a bottom gate thin film transistor, a dual gate thin film transistor or other suitable transistor, but not limited thereto. For instance, in FIG. 1 to FIG. 3, the transistor 120 may include a semiconductor layer SM, a gate electrode GE, a source electrode SE and a drain electrode DE, wherein the semiconductor layer SM may include a channel layer CN overlapping the gate electrode GE in the normal direction of the substrate 110, the gate electrode GE may belong to the conductive layer CTL1, the source electrode SE and the drain electrode DE may belong to the conductive layer CTL2, the gate dielectric layer GI may be disposed between the semiconductor layer SM and the conductive layer CTL1 (more precisely, the gate dielectric layer GI may be disposed between the channel layer CN and the gate electrode GE), and the insulating layer IL1 may be disposed between the conductive layer CTL1 and the conductive layer CTL2 (more precisely, the insulating layer IL1 may be disposed between the gate electrode SE and the source electrode SE and/or between the gate electrode SE and the drain electrode DE), but not limited thereto. For example, in FIG. 1 and FIG. 2, the source electrode SE may be connected to the semiconductor layer SM through a hole H1, and the drain electrode DE may be connected to the semiconductor layer SM through a hole H2. In the present disclosure, the number of the transistor(s) 120 disposed in the sub-pixel SP may be designed based on requirement(s).

In FIG. 2, the transistor 120 may be disposed on the buffer layer BF (i.e., the buffer layer BF may be between the substrate 110 and the transistor 120), and the insulating layer IL2, the insulating layer IL3 and the transparent conductive layer CTL3 may be disposed on the transistor 120.

The display device 100 may include a plurality of pixel electrodes PXE, and one pixel electrode PXE is disposed in one sub-pixel SP of the active region AR. In one sub-pixel SP of the display device 100, the status of the display medium materials in the display medium layer may be correspondingly adjusted based on a signal received by the pixel electrode PXE in this sub-pixel SP (e.g., a data signal or a signal related to the data signal), so as to adjust the light transmittance of this sub-pixel SP, thereby making the light intensity of the backlight passing through this sub-pixel SP be corresponding to the data signal. In FIG. 2 and FIG. 3, the pixel electrode PXE may belong to the transparent conductive layer CTL3 and be electrically connected to at least one transistor 120 in the sub-pixel SP. For instance, the pixel electrode PXE may be electrically connected to the drain electrode DE (or the source electrode SE) of the transistor 120, but not limited thereto. Note that the pixel electrode PXE is omitted in FIG. 1 to make FIG. 1 clear and concise.

As shown in FIG. 2, in cross-sectional view, since the insulating layer IL2 and the insulating layer IL3 are between the transparent conductive layer CTL3 and the transistor 120, the display device 100 may include a connecting hole CTH passing through the insulating layer IL2 and the insulating layer IL3, such that the pixel electrode PXE of the transparent conductive layer CTL3 may be electrically connected to the transistor 120 (e.g., the pixel electrode PXE may be electrically connected to the drain electrode DE or the source electrode SE in the conductive layer CTL2) through the connecting hole CTH.

Moreover, the display device 100 may further include a common electrode configured to receive a common signal, such that the status of the display medium materials in the display medium layer may be controlled by an electric field caused by the pixel electrode PXE and the common electrode. In the present disclosure, the common electrode may be disposed at any suitable position. For example, the common electrode may be disposed between the substrate 110 and the display medium layer or between the opposite substrate and the display medium layer.

The display device 100 may further include other suitable electronic component disposed in the sub-pixel SP of the active region AR. For example, the display device 100 may optionally include a capacitor disposed in the sub-pixel SP, and the number of the capacitor(s) may be designed based on requirement(s), but not limited thereto. In one sub-pixel SP of an embodiment, at least one transistor 120, the capacitor (optionally) and the pixel electrode PXE may be electrically connected to each other to form a sub-pixel circuit, and the number of the transistor(s) 120 in one sub-pixel SP and the number of the capacitor(s) in one sub-pixel SP may be related to the design of the sub-pixel circuit.

As shown in FIG. 1 and FIG. 3, the display device 100 may further include a plurality of data lines DL configured to transmit the data signals, wherein the data line DL may be electrically connected to the transistor 120 in the sub-pixel SP, such that the signal received by the pixel electrode PXE may be corresponding to the data signal transmitted by the data line DL (e.g., the signal received by the pixel electrode PXE may be the data signal). In FIG. 3, the data line DL may belong to the conductive layer CTL2, but not limited thereto.

As shown in FIG. 1 and FIG. 2, the display device 100 may further include a plurality of scan lines SL configured to transmit switching signals, wherein the scan line SL may be electrically connected to the transistor 120 in the sub-pixel SP, and the switch status of the transistor 120 electrically connected to the scan line SL may be controlled by the switching signal. In FIG. 2, the scan line SL may belong to the conductive layer CTL1, but not limited thereto.

In the present disclosure, the disposition of the data lines DL and the disposition of the scan lines SL may be designed based on requirement(s). In some embodiments (as shown in FIG. 1), the data lines DL may (substantially) extend along the direction Y and be arranged in the direction X, but not limited thereto. In some embodiments (as shown in FIG. 1), the scan lines SL may (substantially) extend along the direction X and be arranged in the direction Y, but not limited thereto.

In some embodiments, an array substrate structure AYS may include the substrate 110 and the structures disposed between the substrate 110 and the display medium layer. Therefore, according to above, the array substrate structure AYS shown in FIG. 1 to FIG. 3 may include the substrate 110, the buffer layer BF, the semiconductor layer SM, the gate dielectric layer GI, the conductive layer CTL1, the insulating layer IL1, the conductive layer CTL2, the insulating layer IL2, the insulating layer IL3 and the transparent conductive layer CTL3, and the electronic components included in these layers may belong to the array substrate structure AYS also.

In the present disclosure, the display device 100 includes a color filter 130 disposed on the substrate 110, wherein the color filter 130 to convert (or filter) the color of the light passing through the color filter 130 into required color. In some embodiments, the thickness of the color filter 130 may range from 1.5 μm to 3 μm, but not limited thereto. In FIG. 1 to FIG. 3, the color filter 130 may include a plurality of color filter parts 130a disposed in the sub-pixels SP respectively (i.e., the relation between the color filter parts 130a and the sub-pixels SP may be the one-to-one correspondence), wherein the color(s) of the color filter part 130a included in the color filter 130 may be designed based on requirement(s). For example, since the display device 100 is a color display device, the color filter 130 may have a first color filter part 130al (e.g., a red color filter part) corresponding to the first sub-pixel SP1, a second color filter part 130a2 (e.g., a green color filter part) corresponding to the second sub-pixel SP2 and a third color filter part 130a3 (e.g., a blue color filter part) corresponding to the third sub-pixel SP3, but not limited thereto.

In the present disclosure, the color filter 130 may be disposed between the substrate 110 and the display medium layer, such that the color filter 130 may belong to the array substrate structure AYS, thereby making the display device 100 be a COA (color filter on array) type display device. As shown in FIG. 2 to FIG. 3, the insulating layer IL3 and the transparent conductive layer CTL3 may be disposed on the color filter 130, such that the color filter 130 may be between the substrate 110 and the insulating layer IL3 and between the substrate 110 and the transparent conductive layer CTL3.

As shown in FIG. 1 to FIG. 3, a portion of the color filter 130 may overlap the transistor 120 in the horizontal direction (e.g., the direction Y). In detail, after forming the buffer layer BF, the semiconductor layer SM, the gate dielectric layer GI, the conductive layer CTL1, the insulating layer IL1, the conductive layer CTL2 and the insulating layer IL2 to form the included electronic components (e.g., the transistor 120, the data line DL, the scan line SL, etc.), an etching process is performed to remove a part of at least one layer in the sub-pixel SP for forming an opening OP in the sub-pixel SP. Then, the color filter 130 is formed in the sub-pixel SP and a portion of the color filter 130 is filled in the opening OP, such that a portion of the color filter 130 overlaps the transistor 120 in the horizontal direction. For example, in FIG. 2 and FIG. 3, the etching process may remove a part of the insulating layer IL2, a part of the insulating layer IL1, a part of the gate dielectric layer GI and a part of the buffer layer BF to form the opening OP, such that the insulating layer IL2 may have a side surface SS4 serving as the edge of the opening OP, the insulating layer IL1 may have a side surface SS3 serving as the edge of the opening OP, the gate dielectric layer GI may have a side surface SS2 serving as the edge of the opening OP, and the buffer layer BF may have a side surface SS1 serving as the edge of the opening OP, but not limited thereto. In some cases, the etching process may optionally remove a part of the substrate 110, such that a thickness of a portion of the substrate 110 corresponding to the opening OP may be less than a thickness of other portion of the substrate 110, but not limited thereto. In some embodiments, the color filter 130 may overlap the transistor 120, but not limited thereto.

The etching process may cause an oblique etching on the insulating layer IL2, the insulating layer IL1, the gate dielectric layer GI and/or the buffer layer BF, such that the side surface SS4 of the insulating layer IL2, the side surface SS3 of the insulating layer IL1, the side surface SS2 of the gate dielectric layer GI and/or the side surface SS1 of the buffer layer BF may be inclined surfaces relative to a top surface of the substrate 110 and not be perpendicular to the top surface of the substrate 110. For instance (as shown in FIG. 2), an angle AG between the side surface SS4 of the insulating layer IL2 and a bottom surface of the insulating layer IL2 may be greater than or equal to 55 degrees and less than or equal to 90 degrees, wherein the angle AG may be such as 60 degrees, 65 degrees, 70 degrees, 75 degrees, 80 degrees or 85 degrees, but not limited thereto. In some cases, the etching process may cause an arc angle between a top surface and a side surface of the topmost layer of the etched structure (e.g., in FIG. 2 and FIG. 3, the insulating layer IL2 may have an arc angle generated between the top surface and the side surface SS4), but not limited thereto.

In FIG. 2 and FIG. 3, each color filter part 130a of the color filter 130 may include a first portion 132 disposed outside the opening OP and a second portion 134 disposed in the opening OP and adjacent to the first portion 132. Therefore, the first portion 132 is disposed on the buffer layer BF, the gate dielectric layer GI, the insulating layer IL1 and the insulating layer IL2, and the second portion 134 is directly in contact with the side surface SS1 of the buffer layer BF, the side surface SS2 of the gate dielectric layer GI, the side surface SS3 of the insulating layer IL1 and the side surface SS4 of the insulating layer IL2. In FIG. 2 and FIG. 3, the first portion 132 of the color filter 130 overlaps the top surface of the insulating layer IL2 in the direction Z (i.e., the normal direction of the substrate 110), and the second portion 134 of the color filter 130 does not overlap the top surface of the insulating layer IL2 in the direction Z (i.e., the normal direction of the substrate 110). In some embodiments (as shown in FIG. 2 and FIG. 3), the first portion 132 of the color filter 130 (or a bottom surface of the first portion 132 of the color filter 130) may be directly in contact with the insulating layer IL2, and the second portion 134 of the color filter 130 (or a bottom surface of the second portion 134 of the color filter 130) may be directly in contact with the substrate 110, but not limited thereto.

As shown in FIG. 2 and FIG. 3, since the first portion 132 of the color filter 130 is disposed outside the opening OP and disposed on the insulating layer IL2, and the second portion 134 of the color filter 130 is disposed in the opening OP and directly in contact with the side surface SS4 of the insulating layer IL2, a first color filter thickness T1 of the first portion 132 is different from a second color filter thickness T2 of the second portion 134. In FIG. 2 and FIG. 3, the first color filter thickness T1 of the first portion 132 may be less than the second color filter thickness T2 of the second portion 134. In the description and following claims, the first color filter thickness T1 is a minimum thickness of the first portion 132 in the direction Z (a minimum distance between two opposite surfaces of the first portion 132 in the direction Z), and the second color filter thickness T2 is a maximum thickness of the second portion 134 in the direction Z (a maximum distance between two opposite surfaces of the second portion 134 in the direction Z). Note that the second color filter thickness T2 may be referred as the thickness of the color filter 130.

In the present disclosure, the display device 100 may further include a light shielding layer 140 disposed on the substrate 110, wherein the light shielding layer 140 is configured to shield some components, so as to reduce the probability that an external light is reflected by the display device 100 and/or to reduce the probability that the backlight passes through a region shielded by the light shielding layer 140, thereby enhancing the displaying quality. For instance, the light shielding layer 140 may include metal, photoresist, ink, resin, pigment, other suitable light shielding material(s) or a combination thereof, but not limited thereto. In some embodiments, the light shielding layer 140 may be one conductive layer disposed on the conductive layer CTL2, and the light shielding layer 140 may overlap the data line DL and/or the scan line SL in the normal direction of the substrate 110. In another embodiment, the light shielding layer 140 may be two conductive layers disposed on the conductive layer CTL2, wherein one of these conductive layers may overlap the data line DL and the other may overlap the scan line SL in the normal direction of the substrate 110, but not limited thereto.

In the present disclosure, the light shielding layer 140 may be disposed between the substrate 110 and the display medium layer, such that the light shielding layer 140 may belong to the array substrate structure AYS. In FIG. 1 to FIG. 3, the light shielding layer 140 may be disposed on the color filter 130 and the insulating layer IL2, and the light shielding layer 140 may surround each color filter part 130a to shield the edge of the color filter part 130a and at least a portion of the data line DL. In some embodiments (as shown in FIG. 2 and FIG. 3), the insulating layer IL3 and the transparent conductive layer CTL3 may be disposed on the light shielding layer 140. In some embodiments (as shown in FIG. 2 and FIG. 3), the light shielding layer 140 may be disposed on the first portion 132 of the color filter 130 and overlap the first portion 132 of the color filter 130 in the direction Z, and the light shielding layer 140 may overlap or not overlap the second portion 134 of the color filter 130 in the direction Z based on requirement(s) (in FIG. 1 to FIG. 3, the light shielding layer 140 may not overlap the second portion 134 of the color filter 130). In some embodiments, an edge of the light shielding layer 140 may overlap the side surface of the insulating layer under the light shielding layer 140 in the direction Z, or an edge of the light shielding layer 140 may extend beyond the side surface of the insulating layer under the light shielding layer 140 and overlap the second portion 134 of the color filter 130 in the direction Z, but not limited thereto. For example (not shown in figures), the light shielding layer 140 may be disposed on the first portion 132 and extend towards the opening OP, such that an edge of the light shielding layer 140 may overlap the side surface SS4 of the insulating layer IL2 in the direction Z, or an edge of the light shielding layer 140 may extend beyond the side surface SS4 of the insulating layer IL2 and overlap the second portion 134 of the color filter 130 in the direction Z, but not limited thereto.

In the present disclosure, since the light shielding layer 140 may surround each color filter part 130a, the light shielding layer 140 may define a light-emitting region of the sub-pixel SP. In FIG. 1, the light-emitting region of the sub-pixel SP may be a region in the sub-pixel SP surrounded by the light shielding layer 140, the pixel aperture ratio of the sub-pixel SP is a ratio of an area of the light-emitting region to an area of the sub-pixel SP.

Normally, a side surface of the connecting hole CTH may be an inclined surface and not be parallel to the direction Z. Thus, if a minimum distance between a top surface of a topmost insulating layer (i.e., the insulating layer IL3) through which the connecting hole CTH passes and the drain electrode DE (the conductive layer CTL2) of the transistor 120 in the direction Z is greater, the size of the connecting hole CTH in the horizontal direction is larger (i.e., the size of the connecting hole CTH is related to the minimum distance between the top surface of the insulating layer IL3 and the conductive layer CTL2 in the direction Z). If the size of the connecting hole CTH in the horizontal direction is smaller, a distance between two adjacent color filter parts 130a of the color filter 130 in the direction Y is able to be smaller, such that the area of the light-emitting region of the sub-pixel SP is increased, thereby enhancing the pixel aperture ratio of the sub-pixel SP.

In the present disclosure, since the opening OP exists and the second portion 134 of the color filter 130 is disposed in the opening OP, and the first color filter thickness T1 of the first portion 132 of the color filter 130 is less than the second color filter thickness T2 of the second portion 134 of the color filter 130, the minimum distance between the top surface of the insulating layer IL3 and the conductive layer CTL2 in the direction Z is reduced to decrease the size of the connecting hole CTH in the horizontal direction, such that distance between two adjacent color filter parts 130a of the color filter 130 in the direction Y is reduced, thereby enhancing the pixel aperture ratio of the sub-pixel SP. Furthermore, since the minimum distance between the top surface of the insulating layer IL3 and the conductive layer CTL2 in the direction Z is reduced, a depth of the connecting hole CTH in the direction Z (i.e., the vertical direction) is decreased, so as to improve the yield rate of the connecting hole CTH, thereby improving the yield rate of the display device 100.

A manufacturing method of the display device 100 is described in the following. In the following manufacturing method, a forming process of a layer and/or a structure may include an atomic layer deposition (ALD), a chemical vapor deposition (CVD), a physical vapor deposition (PVD), a coating process, any other suitable process or a combination thereof. In the following manufacturing method, a patterning process may include a photolithography, an etching process, any other suitable process or a combination thereof, wherein the etching process may be a wet etching process, a dry etching process, any other suitable etching process, or a combination thereof. In addition, the process sequence of the manufacturing method of the display device 100 may be adjusted based on requirement(s).

In the manufacturing method of the display device 100 of the present disclosure, as shown in FIG. 2 and FIG. 3, the buffer layer BF, the semiconductor layer SM, the gate dielectric layer GI, the conductive layer CTL1 (e.g., the conductive layer CTL1 includes the gate electrode GE and the scan line SL), the insulating layer IL1, the conductive layer CTL2 (e.g., the conductive layer CTL2 includes the data line DL, the source electrode SE and the drain electrode DE) and the insulating layer IL2 are formed on the provided substrate 110 in sequence, and patterning process(es) may be applied on these layers based on requirement(s).

Then, as shown in FIG. 2 and FIG. 3, a part of the buffer layer BF, a part of the gate dielectric layer GI, a part of the insulating layer IL1 and a part of the insulating layer IL2 are removed by an etching process, so as to form the opening OP. For instance, the etching process forming the opening OP may be a dry etching process, but not limited thereto. Afterwards, the color filter 130 is formed on the substrate 110, such that the first portion 132 of the color filter 130 is disposed on the insulating layer IL2 and disposed outside the opening OP, and the second portion 134 of the color filter 130 is disposed in the opening OP and adjacent to the first portion 132.

Then, the light shielding layer 140 is formed on the color filter 130, and the insulating layer IL3 is formed on the color filter 130 and the light shielding layer 140. Afterwards, another part of the insulating layer IL2 and a part of the insulating layer IL3 are removed by another etching process, so as to form the connecting hole CTH. The transparent conductive layer CTL3 is formed on the insulating layer IL3, and the pixel electrode PXE is connected to the transistor 120 through the connecting hole CTH. Accordingly, the array substrate structure AYS of the display device 100 is formed by aforementioned processes.

After forming the array substrate structure AYS, the array substrate structure AYS and the opposite substrate are assembled and arranged opposite to each other, and the display medium layer is disposed between the array substrate structure AYS and the opposite substrate.

The display device and its manufacturing method of the present disclosure are not limited to the above embodiments. Further embodiments of the present disclosure are described below. For ease of comparison, same components will be labeled with the same symbol in the following. The following descriptions relate the differences between each of the embodiments, and repeated parts will not be redundantly described.

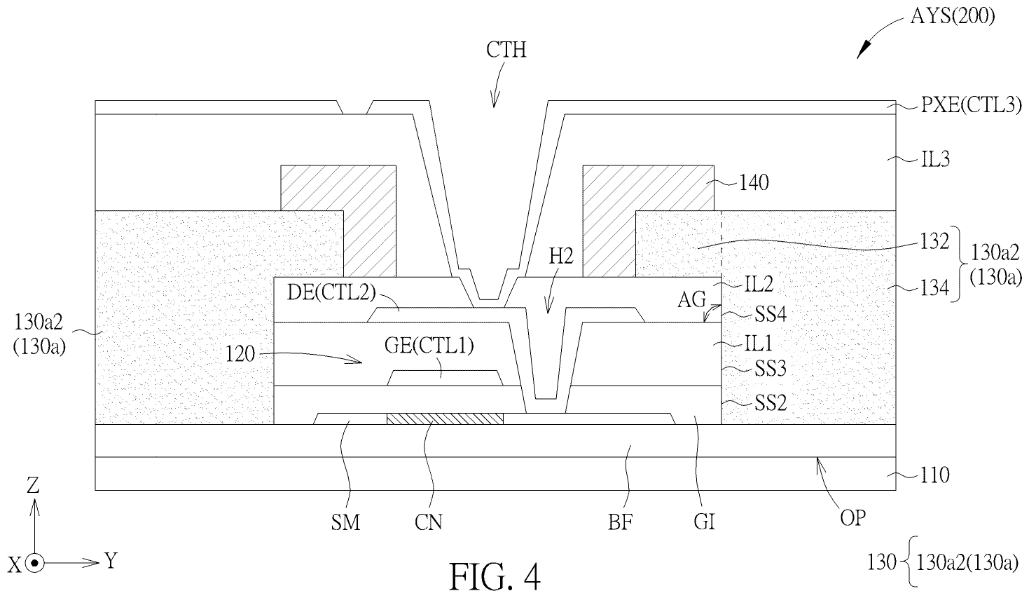

Referring to FIG. 4, FIG. 4 is a schematic diagram showing a cross-sectional view of a display device according to a second embodiment of the present disclosure. As shown in FIG. 4, a difference between the first embodiment and this embodiment is that the buffer layer BF in the opening OP of the display device 200 of this embodiment is not removed or is not completely removed, such that the second portion 134 of the color filter 130 (or the bottom surface of the second portion 134 of the color filter 130) is directly in contact with the buffer layer BF. In some embodiments (not shown in figures), a thickness of a portion of the buffer layer BF overlapping the opening OP may be less than a thickness of another portion of the buffer layer BF not overlapping the opening OP, but not limited thereto.

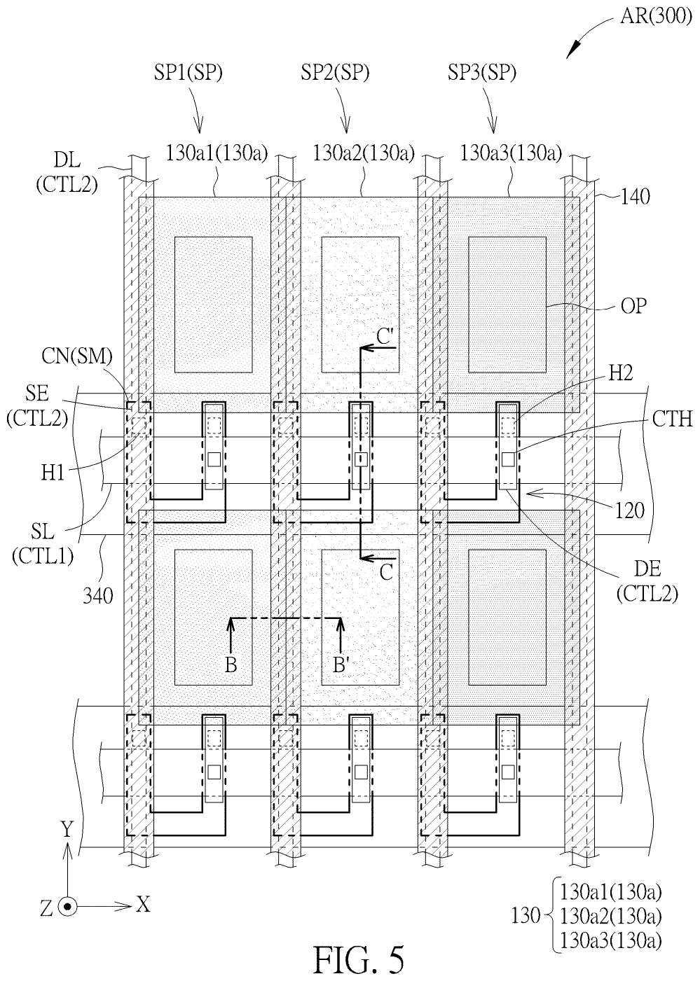

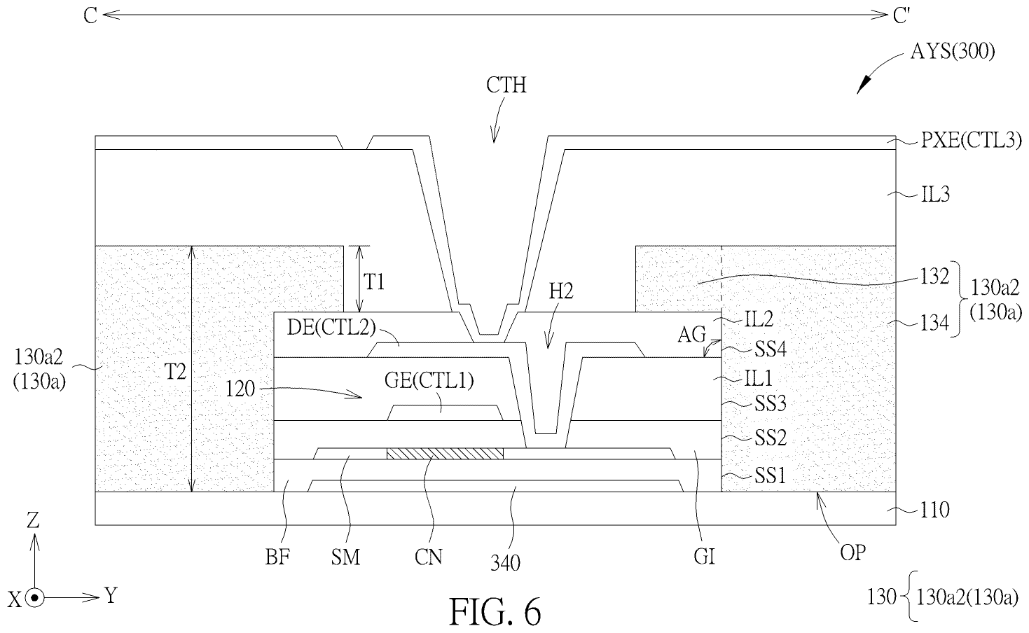

Referring to FIG. 5 and FIG. 6, FIG. 5 is a schematic diagram showing a top view of a display device according to a third embodiment of the present disclosure, and FIG. 6 is a schematic diagram showing a cross-sectional view of a structure taken along a cross-sectional line C-C′ in FIG. 5, wherein the structure taken along the cross-sectional line B-B′ of FIG. 5 is the same as the structure shown in FIG. 3, and the pixel electrode PXE is omitted in FIG. 5 to make FIG. 5 clear and concise. As shown in FIG. 5 and FIG. 6, a difference between the first embodiment and this embodiment is a light-shielding design of the display device 300 of this embodiment. In FIG. 3, FIG. 5 and FIG. 6, the light shielding layer 140 may be disposed between the adjacent color filter parts 130a in the direction X, and the light shielding layer 140 may be a strip structure extending along the direction Y to shield a portion of the edge of the color filter part 130a and at least a portion of the data line DL.

In FIG. 5 and FIG. 6, the display device 300 may further include a light shielding bottom structure 340 configured to shield some components, so as to reduce the probability that an external light is reflected by the display device 300 and/or to reduce the probability that the backlight passes through a region shielded by the light shielding bottom structure 340. As shown in FIG. 5 and FIG. 6, the light shielding bottom structure 340 may be disposed between the adjacent color filter parts 130a in the direction Y, and the light shielding bottom structure 340 may be a strip structure extending along the direction X to shield a portion of the edge of the color filter part 130a and the structures between the adjacent color filter parts 130a in the direction Y (e.g., these structures may be the transistor 120, the connecting hole CTH, the scan line SL, etc.). In FIG. 5 and FIG. 6, the light shielding bottom structure 340 overlaps the first portion 132 of the color filter 130 in the direction Z.

In the display device 300, the light shielding bottom structure 340 may be disposed at any suitable position. For instance, as shown in FIG. 6, the light shielding bottom structure 340 may be disposed between the substrate 110 and the buffer layer BF (i.e., during the process of manufacturing the display device 300, the light shielding bottom structure 340 may be formed before forming the buffer layer BF), and the light shielding bottom structure 340 may belong to the array substrate structure AYS, but not limited thereto. Furthermore, the light shielding bottom structure 340 may include metal, photoresist, ink, resin, pigment, other suitable light shielding material(s) or a combination thereof.

In the present disclosure, the existence of the opening OP not only reduces the size of the connecting hole CTH in the horizontal direction and reduces the distance between the adjacent color filter parts 130a in the direction Y, but also reduces the size of the light shielding bottom structure 340 in the direction Y, so as to enhance the pixel aperture ratio of the sub-pixel SP.

In summary, in the present disclosure, since the opening exists and the second portion of the color filter is disposed in the opening, and the first color filter thickness of the first portion of the color filter is less than the second color filter thickness of the second portion of the color filter, the size of the connecting hole in the horizontal direction and the depth of the connecting hole in the vertical direction are reduced, so as to enhance the pixel aperture ratio of the sub-pixel and the yield rate of the display device.

Although the embodiments and their advantages of the present disclosure have been described as above, it should be understood that any person having ordinary skill in the art can make changes, substitutions, and modifications without departing from the spirit and scope of the present disclosure. In addition, the protecting scope of the present disclosure is not limited to the processes, machines, manufactures, material compositions, devices, methods and steps in the specific embodiments described in the description. Any person having ordinary skill in the art can understand the current or future developed processes, machines, manufactures, material compositions, devices, methods and steps from the content of the present disclosure, and then, they can be used according to the present disclosure as long as the same functions can be implemented or the same results can be achieved in the embodiments described herein. Thus, the protecting scope of the present disclosure includes the above processes, machines, manufactures, material compositions, devices, methods and steps. Moreover, each claim constitutes an individual embodiment, and the protecting scope of the present disclosure also includes the combination of each claim and each embodiment. The protecting scope of the present disclosure shall be determined by the appended claims.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A display device, comprising:
a substrate;
a transistor disposed on the substrate;
an insulating layer disposed on the transistor and comprising a side surface; and
a color filter disposed on the substrate and comprising a first portion disposed on the insulating layer and a second portion adjacent to the first portion, wherein the second portion is in contact with the side surface of the insulating layer;
wherein a first color filter thickness of the first portion is less than a second color filter thickness of the second portion.

2. The display device according to claim 1, wherein the first portion of the color filter is in contact with the insulating layer, and the second portion of the color filter is in contact with the substrate.

3. The display device according to claim 1, further comprising a buffer layer disposed between the substrate and the transistor, wherein the color filter is disposed on the buffer layer.

4. The display device according to claim 3, wherein the first portion of the color filter is in contact with the insulating layer, and the second portion of the color filter is in contact with the buffer layer.

5. The display device according to claim 3, wherein the second portion of the color filter is in contact with a side surface of the buffer layer.

6. The display device according to claim 3, further comprising a light shielding bottom structure disposed between the substrate and the buffer layer.

7. The display device according to claim 6, wherein the light shielding bottom structure overlaps the first portion of the color filter in a normal direction of the substrate.

8. The display device according to claim 1, wherein the insulating layer has an arc angle.

9. The display device according to claim 1, wherein the first portion of the color filter overlaps a top surface of the insulating layer in a normal direction of the substrate, and the second portion of the color filter does not overlap the top surface of the insulating layer in the normal direction of the substrate.

10. The display device according to claim 1, further comprising:
a connecting hole passing through the insulating layer; and
a transparent conductive layer disposed on the transistor and the color filter, wherein the transparent conductive layer is electrically connected to the transistor through the connecting hole.

11. The display device according to claim 10, further comprising another insulating layer disposed between the transparent conductive layer and the color filter, wherein the another insulating layer overlaps the first portion and the second portion of the color filter in a normal direction of the substrate, and the connecting hole further passes through the another insulating layer.

12. The display device according to claim 1, further comprising a light shielding layer disposed on the first portion of the color filter.

13. The display device according to claim 12, wherein the light shielding layer is in contact with the insulating layer and the first portion of the color filter.

14. The display device according to claim 1, further comprising a gate dielectric layer disposed on the substrate, wherein the transistor comprises a semiconductor layer and a gate electrode, the gate dielectric layer is disposed between the semiconductor layer and the gate electrode, and the second portion of the color filter is in contact with a side surface of the gate dielectric layer.

15. The display device according to claim 1, wherein an angle between the side surface of the insulating layer and a bottom surface of the insulating layer is greater than or equal to 55 degrees and less than or equal to 90 degrees.

16. A manufacturing method of a display device, comprising:
providing a substrate;
forming a semiconductor layer on the substrate;
forming a gate dielectric layer on the semiconductor layer;
forming a gate electrode on the gate dielectric layer;
forming an insulating layer on the gate electrode;
removing a part of the gate dielectric layer and a part of the insulating layer to form an opening; and
forming a color filter on the insulating layer and in the opening;
wherein a portion of the color filter disposed in the opening is in contact with a side surface of the gate dielectric layer and a side surface of the insulating layer.

17. The manufacturing method according to claim 16, further comprising:
forming another insulating layer on the insulating layer and the color filter;
removing a part of the another insulating layer and another part of the insulating layer to form a connecting hole passing through the another insulating layer and the insulating layer; and
forming a transparent conductive layer on the color filter and the another insulating layer, wherein a portion of the transparent conductive layer is disposed in the connecting hole.

18. The manufacturing method according to claim 16, wherein the color filter comprises a first portion disposed on the insulating layer and a second portion disposed in the opening, the first portion and the second portion are connected to each other, and the second portion is in contact with the side surface of the gate dielectric layer and the side surface of the insulating layer.

19. The manufacturing method according to claim 18, wherein the first portion of the color filter overlaps a top surface of the insulating layer in a normal direction of the substrate, and the second portion of the color filter does not overlap the top surface of the insulating layer in the normal direction of the substrate.

20. The manufacturing method according to claim 18, wherein a first color filter thickness of the first portion is less than a second color filter thickness of the second portion.
